(19) United States
(12) Patent Application Publication
(10) Pub. No.: US 2025/0096006 A1
(43) Pub. Date: Mar. 20, 2025

(54) ETCHING METHOD AND PLASMA PROCESSING APPARATUS

(71) Applicant: Tokyo Electron Limited, Tokyo (JP)

(72) Inventors: Rin SASAKI, Kurokawa-gun (JP); Masanori HOSOYA, Kurokawa-gun (JP); Yuki CHIBA, Kurokawa-gun, Miyagi (JP); Shun ITOH, Kurokawa-gun, Miyagi (JP); Daisuke NISHIDE, Hsinchu Science Park (TW); Takatoshi ORUI, Hillsboro, OR (US); Yuto SAITO, Kurokawa-gun (JP)

(73) Assignee: Tokyo Electron Limited, Tokyo (JP)

(21) Appl. No.: 18/964,049

(22) Filed: Nov. 29, 2024

Related U.S. Application Data
(63) Continuation of application No. PCT/JP2023/020130, filed on May 30, 2023.

(30) Foreign Application Priority Data
Jun. 8, 2022 (JP) 2022-093071
Jun. 8, 2022 (JP) 2022-093119

(51) Int. Cl. H01L 21/311; H01J 37/305; H01J 37/32

(52) U.S. Cl. CPC H01L 21/31116; H01J 37/3053; H01J 37/32091; H01J 37/32449

(57) ABSTRACT

A disclosed etching method includes (a) preparing a substrate in a chamber, (b) forming a deposit on the substrate, (c) supplying ions from a plasma generated from the process gas to the deposit to modify the deposit, and (d) etching the dielectric film by using a plasma after (c). The substrate includes a dielectric film and a mask. The deposit is supplied from a plasma generated from a process gas containing a gas component containing fluorine and carbon. A power level of a source radio frequency power in (c) is not higher than a power level of the source radio frequency power in (b). An electric bias has a level in (c) higher than a level of the electric bias in (b), or is not supplied in (b). A level of the electric bias in (d) is higher than the level of the electric bias in (c).

### CROSS-REFERENCE TO RELATED APPLICATIONS

This application is a continuation application of PCT Application No. PCT/JP2023/020130, filed on May 30, 2023, which claims the benefit of priority from Japanese Patent Application No. 2022-093071, filed on Jun. 8, 2022, and Japanese Patent Application No. 2022-093119, filed on Jun. 8, 2022. The entire contents of the above listed PCT and priority applications are incorporated herein by reference.

### BACKGROUND

### Field

Example embodiments of the present disclosure relate to an etching method and a plasma processing apparatus.

### Description of the Related Art

A plasma processing apparatus is used for plasma etching to be performed on a film of a substrate. The plasma processing apparatus includes a chamber and a substrate support. The substrate support is provided in the chamber. When the plasma etching is performed, a source radio frequency power is supplied for generating a plasma. In addition, in order to attract ions into the substrate, a bias radio frequency power is supplied to the substrate support. Japanese Unexamined Patent Publication No. 2016-157735 discloses that, in plasma etching, a phase difference between a pulse wave of a source radio frequency power and a pulse wave of a bias radio frequency power is controlled.

### SUMMARY

An etching method is provided in an example embodiment. The etching method includes (a) preparing a substrate on a substrate support in a chamber of a plasma processing apparatus. The substrate includes a dielectric film containing silicon and oxygen and a metal hard mask provided on the dielectric film. The etching method further includes (b) forming a deposit on the substrate. The deposit is supplied from a plasma generated from a process gas containing a gas component containing fluorine and carbon in the chamber. The etching method further includes (c) supplying ions from a plasma generated from the process gas to the deposit to modify the deposit. The etching method further includes (d) etching the dielectric film by using a plasma generated in the chamber after the (c). A power level of a source radio frequency power used to generate the plasma from the process gas in the (c) is equal to or lower than a power level of the source radio frequency power used to generate the plasma from the process gas in the (b). A level of an electric bias supplied to the substrate support in the (c) is higher than a level of the electric bias supplied to the substrate support in the (b), or the electric bias is not supplied to the substrate support in the (b). A level of the electric bias supplied to the substrate support in the (d) is higher than the level of the electric bias supplied to the substrate support in the (c).

The foregoing summary is illustrative only and is not intended to be in any way limiting. In addition to the illustrative aspects, example embodiments, and features described above, further aspects, example embodiments, and features will become apparent by reference to the drawings and the following detailed description.

### BRIEF DESCRIPTION OF THE DRAWINGS

FIG. 1 is a flowchart illustrating an etching method according to an example embodiment.

FIG. 2 is a diagram illustrating a configuration example of a plasma processing system.

FIG. 3 is a diagram illustrating a configuration example of a capacitively coupled plasma processing apparatus.

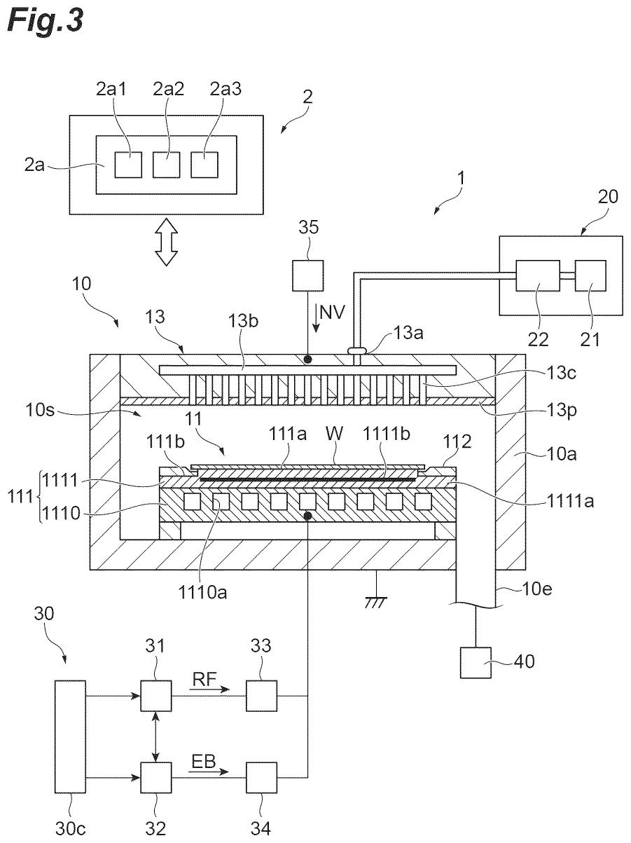

FIG. 4A, FIG. 4B, FIG. 4C, and FIG. 4D are partially enlarged cross-sectional views illustrating an example of a substrate related to each step of the etching method according to the example embodiment.

FIG. 5 is a timing chart related to the etching method according to an example embodiment.

FIG. 6 is a flowchart illustrating an etching method according to another example embodiment.

FIG. 7A, FIG. 7B, FIG. 7C, and FIG. 7D are partially enlarged cross-sectional views illustrating an example of a substrate related to each step of the etching method according to another example embodiment.

FIG. 8 is a diagram illustrating results of an evaluation experiment and a comparative experiment.

FIG. 9 is a flowchart illustrating an etching method according to still another example embodiment.

FIG. 10 is a timing chart related to the etching method according to still another example embodiment.

FIG. 11A, FIG. 11B, and FIG. 11C are partially enlarged cross-sectional views illustrating an example of a substrate related to each step of the etching method according to still another example embodiment.

FIG. 12A, FIG. 12B, FIG. 12C, and FIG. 12D are diagrams illustrating a deposit grown in the etching method according to still another example embodiment.

### DETAILED DESCRIPTION

Hereinafter, various example embodiments will be described in detail with reference to the drawings. In the drawings, the same or equivalent portions are denoted by the same reference symbols.

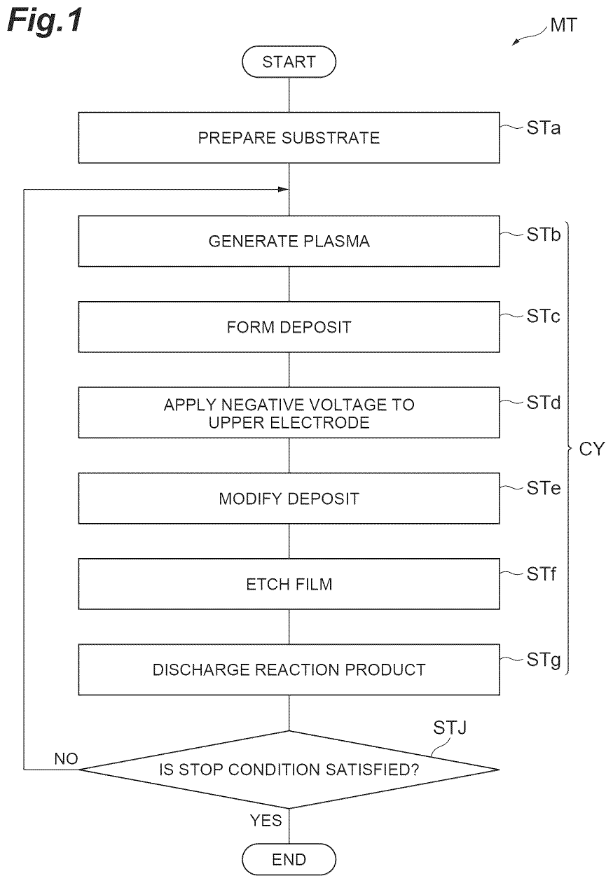

FIG. 1 is a flowchart of an etching method according to an example embodiment. The etching method illustrated in FIG. 1 (hereinafter, referred to as a “method MT”) is performed in a plasma processing apparatus to etch a dielectric film of a substrate.

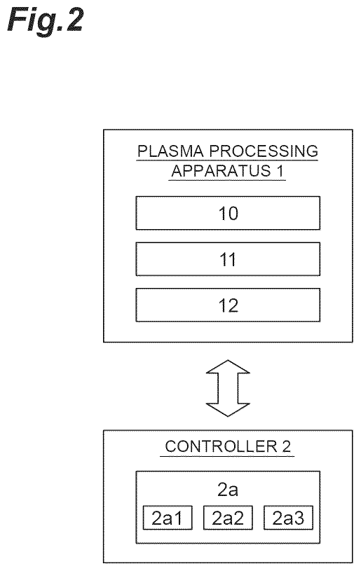

FIG. 2 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP).

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the controller 2 may be partially or entirely incorporated into the plasma processing apparatus 1. The controller 2 may include a processor 2al, a storage 2a2, and a communication interface 2a3. The controller 2 is implemented in, for example, a computer 2a. The processor 2al may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or any combination thereof. The communication interface 2a3 may communicate with the plasma processing apparatus 1 via a communication line, such as a local area network (LAN).

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, a power supply system 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member.

The ring assembly 112 includes one or more annular members. In an embodiment, the annular members include one or more edge rings and at least one cover ring. The edge ring is formed of a conductive or insulating material, whereas the cover ring is formed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

A power supply system 30 includes a radio frequency power supply 31 and a bias power supply 32. The radio frequency power supply 31 configures a plasma generator 12 according to one embodiment. The radio frequency power supply 31 is configured to generate a source radio frequency power RF. The source radio frequency power RF has a source frequency f_{RF}. That is, the source radio frequency power RF has a sinusoidal waveform of which a frequency is the source frequency f_{RF}. The source frequency f_{RF} may be a frequency in a range of 13 MHz to 100 MHz. The radio frequency power supply 31 is electrically coupled to a radio frequency electrode via a matcher 33, and is configured to supply the source radio frequency power RF to the radio frequency electrode. The radio frequency electrode may be provided in a substrate support 11. The radio frequency electrode may be the conductive member of a base 1110 or at least one electrode provided in the ceramic member 1111a. Alternatively, the radio frequency electrode may be the upper electrode. When the source radio frequency power RF is supplied to the radio frequency electrode, a plasma is generated from a gas in a chamber 10.

The matcher 33 has variable impedance. The variable impedance of the matcher 33 is set to reduce the reflection of the source radio frequency power RF from the load. The matcher 33 may be controlled by, for example, a controller 2.

The bias power supply 32 is electrically coupled to the substrate support 11. The bias power supply 32 is electrically coupled to a bias electrode in the substrate support 11, and is configured to supply an electric bias EB to the bias electrode. The bias electrode may be the conductive member of the base 1110 or at least one electrode provided in the ceramic member 1111a. The bias electrode may be common to the radio frequency electrode. When the electric bias EB is supplied to the bias electrode, ions from the plasma are attracted to the substrate W.

The electric bias EB has a waveform cycle and is periodically supplied from the bias power supply 32 to the bias electrode. The waveform cycle of the electric bias EB is defined by a bias frequency. The bias frequency is, for example, a frequency of 100 kHz or higher and 50 MHz or lower. A time length of the waveform cycle of the electric bias EB is the reciprocal of the bias frequency.

The electric bias EB may be a bias radio frequency power having the bias frequency. That is, the electric bias EB may have a sinusoidal waveform of which a frequency is the bias frequency. In this case, the bias power supply 32 is electrically coupled to the bias electrode via a matcher 34. The variable impedance of the matcher 34 is set to reduce the reflection of the bias radio frequency power from the load.

Alternatively, the electric bias EB may include a voltage pulse. The voltage pulse is applied to the bias electrode in the waveform cycle. The voltage pulse is periodically applied to the bias electrode at a time interval having a length that is the same as the time length of the waveform cycle. A waveform of the voltage pulse may be a rectangular wave, a triangular wave, or any waveform. Polarity of a voltage of the voltage pulse is set to cause a potential difference between a substrate W and the plasma to enable the ions from the plasma to be attracted into the substrate W. The voltage pulse may be a negative voltage pulse or a negative direct current voltage pulse. When the electric bias EB includes the voltage pulse, a plasma processing apparatus 1 need not include the matcher 34.

Hereinafter, a level of the electric bias EB may be described. When the electric bias EB is the bias radio frequency power, the level of the electric bias EB is a power level of the bias radio frequency power. When the electric bias EB includes the voltage pulse, the level of the electric bias EB is an absolute value of a negative voltage level of the voltage pulse.

The power supply system 30 may further include a trigger signal generator 30c. The trigger signal generator 30c applies a trigger signal to each of the radio frequency power supply 31 and the bias power supply 32. An output timing of the trigger signal applied to each of the radio frequency power supply 31 and the bias power supply 32 may be designated by the controller 2. The radio frequency power supply 31 generates the source radio frequency power RF or changes the power level thereof at a timing corresponding to the applied trigger signal. In addition, the bias power supply 32 generates the electric bias EB or changes the level of the electric bias EB at a timing corresponding to the applied trigger signal.

The power supply system 30 may further include a power supply 35. The power supply 35 is electrically coupled to the upper electrode. In an embodiment, the upper electrode includes a ceiling plate 13p. The ceiling plate 13p defines an internal space of the chamber 10 from above. That is, the ceiling plate 13p is in contact with the internal space of the chamber 10. The ceiling plate 13p may be made of silicon. The power supply 35 is configured to apply a negative voltage NV (for example, a negative direct current voltage) to the upper electrode. The power supply 35 outputs the negative voltage NV to the upper electrode or changes the absolute value of the voltage level thereof at a timing corresponding to the trigger signal applied from the trigger signal generator 30c. An output timing of the trigger signal applied to the power supply 35 may be designated by the controller 2.

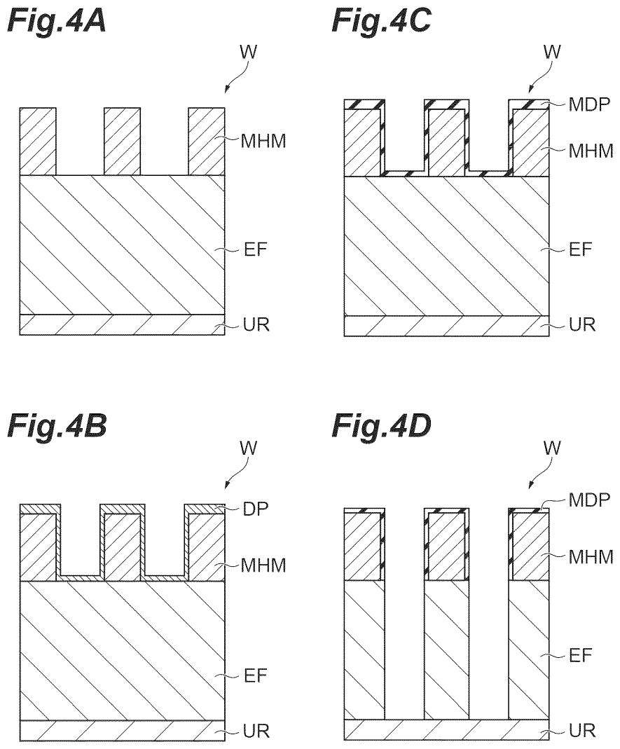

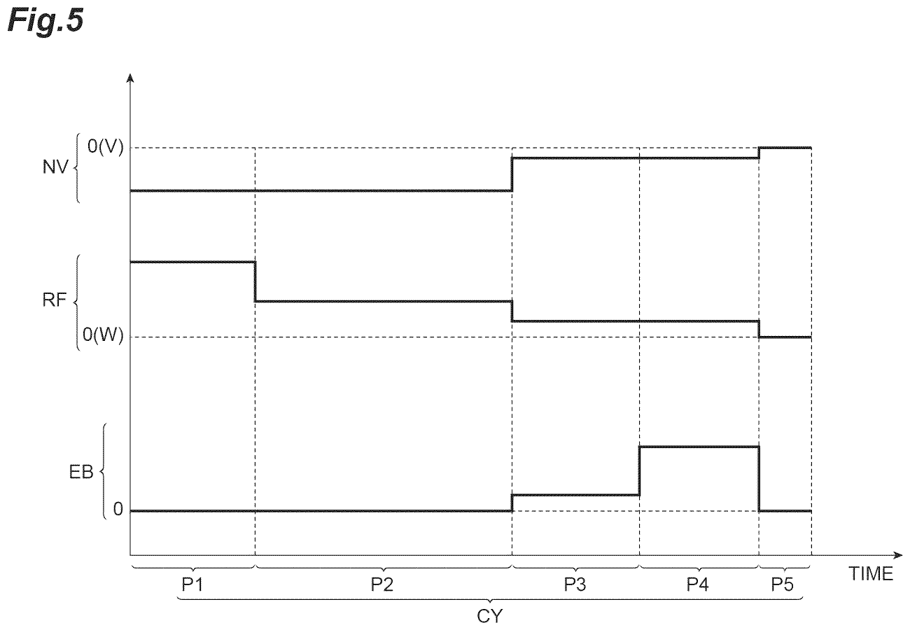

Hereinafter, the method MT will be described with reference to FIG. 4A to FIGS. 4D, and 5, as well as FIG. 1. In addition, the control of each part of the plasma processing apparatus 1 via the controller 2 will also be described. Each of FIG. 4A to FIG. 4D is a partially enlarged cross-sectional view illustrating an example of a substrate related to each step of the etching method according to the example embodiment. FIG. 5 is a timing chart related to the etching method according to an example embodiment. Hereinafter, the method MT will be described with a case where the plasma processing apparatus 1 is used as an example. It should be noted that the method MT may be performed by using a plasma processing apparatus different from the plasma processing apparatus 1.

As illustrated in FIG. 1, the method MT includes Step STa, Step STc, Step STe, and Step STf. The method MT may further include at least one of Step STb, Step STd, or Step STg.

In Step STa, the substrate W is prepared on the substrate support 11 in the chamber 10 of the plasma processing apparatus 1. The steps of the method MT performed after Step STa are performed in a state where the substrate W is placed on the substrate support 11.

As illustrated in FIG. 4A, the substrate W includes a film EF and a mask MHM. The substrate W may further include an underlying region UR. The film EF is a film to be etched in the method MT. The film EF is provided on the underlying region UR. The film EF may be a dielectric film containing silicon and oxygen. The mask MHM is a metal hard mask, and is provided on the film EF. The mask MHM has a pattern transferred to the film EF by etching. That is, the mask MHM is provided with one or more openings. The mask MHM may contain at least one metal selected from the group consisting of titanium, tungsten, molybdenum, and ruthenium. The mask MHM is made of, for example, titanium nitride. The mask MHM may be made of another metal-containing material.

Step STb is performed after Step STa and before Step STc. Step STb is performed in a period P1 (see FIG. 5). In Step STb, the plasma is generated from a process gas in the chamber 10. The process gas is a gas having a deposit property. The process gas contains a gas component containing fluorine and carbon. This gas component may be a fluorocarbon gas, such as a C₄F₈ gas. This gas component may contain a hydrofluorocarbon gas in addition to the fluorocarbon gas or instead of the fluorocarbon gas. The process gas may further contain one or more of a nitrogen gas, an oxygen-containing gas (for example, an oxygen gas), and a noble gas (for example, an Ar gas). In Step STb, the plasma is ignited in the chamber 10, and radicals are generated from the gas component of the process gas.

In Step STb, the controller 2 controls a gas supply 20 to supply the process gas into the chamber 10. In Step STb, the controller 2 controls a gas exhaust system 40 to set a pressure in the chamber 10 to a designated pressure. In Step STb, the controller 2 controls the radio frequency power supply 31 to supply the source radio frequency power RF to the radio frequency electrode to generate the plasma from the process gas. In an embodiment, the power level of the source radio frequency power RF used in Step STb may be higher than the power level of the source radio frequency power RF used in Step STc and Step STe described later. In Step STb, the controller 2 may control the bias power supply 32 not to supply the electric bias EB to the bias electrode. Alternatively, in Step STb, the controller 2 may control the bias power supply 32 to supply the electric bias EB to the bias electrode.

Next, in the method MT, Step STc is performed. In an embodiment, Step STc is performed after Step STb. In an embodiment, Step STc is performed in a period P2 (see FIG. 5). The period P2 is a period after the period P1 or following the period P1.

In Step STc, a deposit DP is formed on the substrate W (see FIG. 4B). The deposit DP is supplied from the plasma generated from the above-described process gas in the chamber 10. That is, the process gas used in Step STb may be the same as the process gas used in Step STc. The deposit DP contains carbon and fluorine.

In Step STc, the controller 2 controls the gas supply 20 to supply the process gas into the chamber 10. In Step STc, the controller 2 controls the gas exhaust system 40 to set the pressure in the chamber 10 to the designated pressure. In Step STc, the controller 2 controls the radio frequency power supply 31 to supply the source radio frequency power RF to the radio frequency electrode to generate the plasma from the process gas. In the embodiment, the power level of the source radio frequency power RF used in Step STc may be lower than the power level of the source radio frequency power RF used in Step STb. In Step STc, the controller 2 may control the bias power supply 32 not to supply the electric bias EB to the bias electrode. Alternatively, in Step STc, the controller 2 may control the bias power supply 32 to supply the electric bias EB to the bias electrode.

Step STd is performed at least in parallel with Step STc. That is, Step STd is performed at least in the period P2. Step STd may be performed in the period P1 in addition to the period P2.

In Step STd, the negative voltage NV is applied to the upper electrode. In Step STd, positive ions are attracted to the ceiling plate 13p from the plasma in the chamber 10. As a result, a substance (for example, silicon) forming the ceiling plate 13p is released. The substance released from the ceiling plate 13p is bonded to the fluorine chemical species in the plasma, to decrease an amount of the fluorine chemical species in the plasma.

In Step STd, the controller 2 controls the power supply 35 to apply the negative voltage NV to the upper electrode. The negative voltage NV may be applied to the upper electrode even in at least one of a period P3 or a period P4, which will be described later. The absolute value of the negative voltage NV applied to the upper electrode in the period P1 and the period P2 may be set to a value greater than the absolute value of the negative voltage NV applied to the upper electrode in the period P3 and the period P4.

Step STe is performed after Step STc. Step STe is performed in the period P3 (see FIG. 5). The period P3 is a period after the period P2 or following the period P2.

In Step STe, the deposit DP is modified by supplying the ions from the plasma generated from the above-described process gas to the deposit DP. In Step STe, as illustrated in FIG. 4C, a deposit MDP is generated from the deposit DP. The process gas used in Step STe may be the same process gas as the process gas used in Step STc. In Step STe, energy of the ions supplied from the plasma to the deposit DP is higher than energy of the ions supplied from the plasma to the substrate W in Step STc. In Step STe, the ions having relatively high energy are supplied to the deposit DP, and elements other than carbon are extracted from the deposit DP. Therefore, in the deposit MDP obtained in Step STe, a large number of carbon-to-carbon bonds having high binding energy may be formed.

In Step STe, the controller 2 controls the gas supply 20 to supply the process gas into the chamber 10. In Step STe, the controller 2 controls the gas exhaust system 40 to set the pressure in the chamber 10 to the designated pressure. In Step STe, the controller 2 controls the radio frequency power supply 31 to supply the source radio frequency power RF to the radio frequency electrode to generate the plasma from the process gas. In the embodiment, the power level of the source radio frequency power RF used in Step STe may be lower than the power level of the source radio frequency power RF used in Step STb. In the embodiment, the power level of the source radio frequency power RF used in Step STe may be equal to or lower than the power level of the source radio frequency power RF used in Step STc. In Step STe, the controller 2 controls the bias power supply 32 to supply the electric bias EB to the bias electrode. In an embodiment, the level of the electric bias EB used in Step STe may be higher than the level of the electric bias EB used in Step STc. In an embodiment, the level of the electric bias EB used in Step STe may be higher than the level of the electric bias EB used in Step STb. As described above, the supply of the electric bias EB may be stopped in at least one of Step STb or Step STc.

Step STf is performed after Step STe. Step STf is performed in the period P4 (see FIG. 5). The period P4 is a period after the period P3 or following the period P3.

In Step STf, the film EF is etched by using a plasma generated in the chamber 10 (FIG. 4D). In Step STf, the plasma may be generated from the above-described process gas. That is, in Step STf, the same process gas as the process gas used in Step STc and Step STe may be used. Alternatively, the process gas used in Step STf may be another gas selected to selectively etch the film EF.

In Step STf, the controller 2 controls the gas supply 20 to supply the process gas into the chamber 10. In Step STf, the controller 2 controls the gas exhaust system 40 to set the pressure in the chamber 10 to the designated pressure. In Step STf, the controller 2 controls the radio frequency power supply 31 to supply the source radio frequency power RF to the radio frequency electrode to generate the plasma from the process gas. In an embodiment, the power level of the source radio frequency power RF used in Step STf may be lower than the power level of the source radio frequency power RF used in Step STb. In am embodiment, the power level of the source radio frequency power RF used in Step STf may be lower than the power level of the source radio frequency power RF used in Step STc. In Step STf, the controller 2 controls the bias power supply 32 to supply the electric bias EB to the bias electrode. In an embodiment, the level of the electric bias EB used in Step STf may be higher than the level of the electric bias EB used in Step STe.

In the method MT, the mask MHM is protected by the deposit MDP from the etching of Step STf. Therefore, according to the method MT, the decrease in the mask MHM due to the etching is suppressed.

The method MT may end after the etching of Step STf. In an embodiment, a cycle CY including Step STc, Step STe, and Step STf may be repeated. The cycle CY may further include at least one of Step STb or Step STd.

The cycle CY may further include Step STg. Step STg is performed after Step STf. Step STg is performed in a period P5 (see FIG. 5). The period P5 is a period after the period P4 or following the period P4.

In Step STg, a reaction product generated in Step STf is discharged from the chamber 10. In Step STg, the plasma need not be generated in the chamber 10.

In Step STg, the controller 2 controls the gas exhaust system 40 to perform the exhaust of the chamber 10 to discharge the reaction product from the chamber 10. In Step STg, the controller 2 may control the radio frequency power supply 31 to stop the supply of the source radio frequency power RF. In Step STg, the controller 2 may control the bias power supply 32 to stop the supply of the electric bias EB.

When the cycle CY is repeated, the method MT further includes Step STJ. In Step STJ, it is determined whether or not a stop condition is satisfied. The stop condition is satisfied when the number of times at which the cycle CY is executed reaches a predetermined number of times. When it is determined that the stop condition is not satisfied in Step STJ, the cycle CY is performed again. When it is determined in Step STJ that the stop condition is satisfied, the method MT ends.

Here, the energies of the ions supplied to the substrate W in the period P1 (Step STb), the period P2 (Step STc), the period P3 (Step STe), and the period P4 (Step STf) are denoted by E₁, E₂, E₃, and E₄, respectively. The power levels of the source radio frequency power RF in the period P1, the period P2, the period P3, and the period P4 are denoted by L_{RF1}, L_{RF2}, L_{RF3}, and L_{RF4}, respectively. In addition, the levels of the electric bias EB in the period P1, the period P2, the period P3, and the period P4 are denoted by L_{EB1}, L_{EB2}, L_{EB3}, and L_{EB4}, respectively. The power level of the source radio frequency power RF and the level of the electric bias EB in each step of the method MT are not limited to the above-described examples as long as 0<E₁ and E₂<E₃<E₄ are satisfied.

For example, the power level of the source radio frequency power RF may satisfy any one of the following (A1) to (A4), and the level of the electric bias EB may satisfy any one of the following (A5) to (A10).

0≤L_{RF4}<L_{RF2}<L_{RF3}<L_{RF1} (A1)

0<L_{RF2}≤L_{RF4}<L_{RF3}<L_{RF1} (A2)

0<L_{RF2}<L_{RF3}≤L_{RF4}<L_{RF1} (A3)

0<L_{RF2}<L_{RF3}<L_{RF1}≤L_{RF4} (A4)

0≤L_{EB1}≤L_{EB2}≤L_{EB3}<L_{EB4} (A5)

0≤L_{EB2}≤L_{EB1}≤L_{EB3}<L_{EB4} (A6)

0≤L_{EB3}≤L_{EB1}≤L_{EB2}<L_{EB4} (A7)

0≤L_{EB3}≤L_{EB2}≤L_{EB1}<L_{EB4} (A8)

0≤L_{EB1}≤L_{EB3}≤L_{EB2}<L_{EB4} (A9)

0≤L_{EB2}≤L_{EB3}<L_{EB1}<L_{EB4} (A10)

Alternatively, the power level of the source radio frequency power RF may satisfy any one of the following (B1) to (B4), and the level of the electric bias EB may satisfy any one of the following (B5) to (B10).

0≤L_{RF4}<L_{RF2}<L_{RF1}<L_{RF3} (B1)

0<L_{RF2}≤L_{RF4}<L_{RF1}<L_{RF3} (B2)

0<L_{RF2}<L_{RF1}≤L_{RF4}<L_{RF3} (B3)

0<L_{RF2}<L_{RF1}<L_{RF3}<L_{RF4} (B4)

0≤L_{EB1}≤L_{EB2}≤L_{EB3}<L_{EB4} (B5)

0≤L_{EB2}≤L_{EB1}≤L_{EB3}<L_{EB4} (B6)

0≤L_{EB3}≤L_{EB1}≤L_{EB2}<L_{EB4} (B7)

0≤L_{EB3}≤L_{EB2}≤L_{EB1}<L_{EB4} (B8)

0≤L_{EB1}≤L_{EB3}≤L_{EB2}<L_{EB4} (B9)

0≤L_{EB2}≤L_{EB3}≤L_{EB1}<L_{EB4} (B10)

Alternatively, the power level of the source radio frequency power RF may satisfy any one of the following (C1) to (C4), and the level of the electric bias EB may satisfy any one of the following (C5) to (C7).

0≤L_{RF4}<L_{RF3}≤L_{RF2}<L_{RF1} (C1)

0<L_{RF3}≤L_{RF4}≤L_{RF2}<L_{RF1} (C2)

0<L_{RF3}<L_{RF2}≤L_{RF4}<L_{RF1} (C3)

0<L_{RF3}≤L_{RF2}<L_{RF1}≤L_{RF4} (C4)

0≤L_{EB1}<L_{EB3}<L_{EB3}<L_{EB4} (C5)

0<L_{EB3}≤L_{EB1}<L_{EB3}<L_{EB4} (C6)

0<L_{EB3}<L_{EB3}≤L_{EB1}<L_{EB4} (C7)

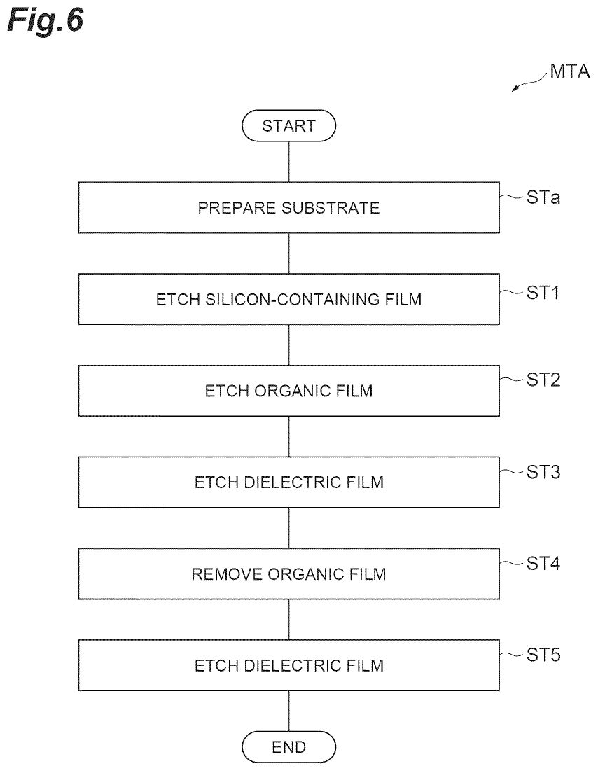

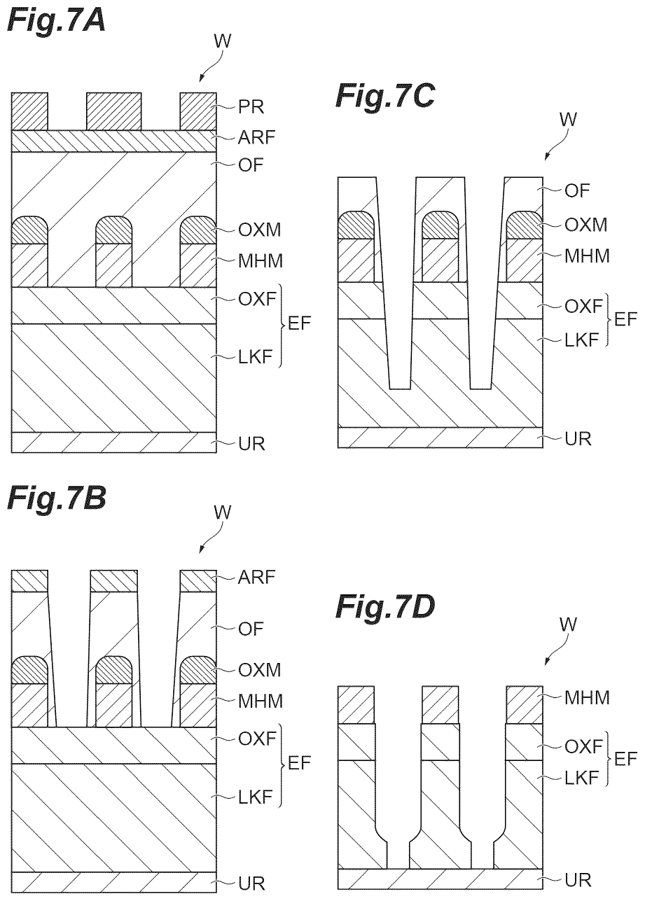

Hereinafter, an etching method according to another example embodiment will be described with reference to FIG. 6 and FIG. 7A to FIG. 7D. FIG. 6 is a flowchart of the etching method according to another example embodiment. Each of FIG. 7A to FIG. 7D is a partially enlarged cross-sectional view illustrating an example of a substrate related to each step of the etching method according to another example embodiment. Hereinafter, the etching method (hereinafter, referred to as a “method MTA”) illustrated in FIG. 6 will be described with a case where the plasma processing apparatus 1 is used as an example. The method MTA may be performed by using a plasma processing apparatus different from the plasma processing apparatus 1.

The method MTA is applied to the substrate W illustrated in FIG. 7A. As illustrated in FIG. 7A, the substrate W includes the underlying region UR, a film EF, the mask MHM, a silicon oxide film OXM, an organic film OF, a silicon-containing film ARF, and a resist mask PR.

The underlying region UR is, for example, an etching stop layer. The underlying region UR may have a laminated structure including an aluminum oxide film and a SiCN film. The film EF is provided on the underlying region UR. The film EF is a dielectric film, and may contain silicon and oxygen. In the embodiment, the film EF may include a low dielectric constant film LKF. The film EF may have a laminated structure including the low dielectric constant film LKF and the silicon oxide film OXF. The low dielectric constant film LKF may be a SiOCH film.

The mask MHM is a metal hard mask, and is provided on the film EF. The mask MHM has a pattern transferred to the film EF by etching. That is, the mask MHM is provided with one or more openings. The mask MHM may contain at least one metal selected from the group consisting of titanium, tungsten, molybdenum, and ruthenium. The mask MHM is made of, for example, titanium nitride. The mask MHM may be made of another metal-containing material.

The silicon oxide film OXM is provided on a top portion of the mask MHM. The organic film OF is provided to cover the silicon oxide film OXM, the mask MHM, and the film EF. The silicon-containing film ARF is provided on the organic film OF. The silicon-containing film ARF may be an anti-reflective film. The resist mask PR is provided on the silicon-containing film ARF. The resist mask PR is patterned by using a photolithography technique. The resist mask PR is provided with one or more openings to form a recess (for example, a trench or a hole) in the film EF at a portion exposed from the mask MHM.

Returning to FIG. 6, the method MTA includes Step STa. In Step STa of the method MTA, as in Step STa of the method MT, the substrate W (FIG. 7A) is prepared on the substrate support 11 in the chamber 10 of the plasma processing apparatus 1. The steps of the method MTA performed after Step STa are performed in a state where the substrate W is placed on the substrate support 11.

In the method MTA, Step ST1 is performed after Step STa. In Step ST1, the silicon-containing film ARF is etched. In Step ST1, the pattern of the resist mask PR is transferred to the silicon-containing film ARF. In Step ST1, the plasma is generated from an etching gas in the chamber 10 to etch the silicon-containing film ARF. The etching gas used in Step ST1 includes a fluorocarbon gas and a noble gas (for example, an Ar gas).

In Step ST1, the controller 2 controls the gas supply 20 to supply the etching gas into the chamber 10. In Step ST1, the controller 2 controls the gas exhaust system 40 to set the pressure in the chamber 10 to the designated pressure. In Step ST1, the controller 2 controls the radio frequency power supply 31 to supply the source radio frequency power RF to the radio frequency electrode to generate the plasma from the etching gas. In Step ST1, the controller 2 may control the bias power supply 32 to supply the electric bias EB to the bias electrode.

Next, Step ST2 is performed. In Step ST2, the organic film OF is etched. By Step ST1, as illustrated in FIG. 7B, the pattern of the silicon-containing film ARF is transferred to the organic film OF. In Step ST2, the plasma is generated from ab etching gas in the chamber 10 to etch the organic film OF. The etching gas used in Step ST2 includes an oxygen-containing gas (for example, an oxygen gas). Alternatively, the etching gas used in Step ST2 may include a nitrogen gas and a hydrogen gas.

In Step ST2, the controller 2 controls the gas supply 20 to supply the etching gas into the chamber 10. In Step ST2, the controller 2 controls the gas exhaust system 40 to set the pressure in the chamber 10 to the designated pressure. In Step ST2, the controller 2 controls the radio frequency power supply 31 to supply the source radio frequency power RF to the radio frequency electrode to generate the plasma from the etching gas. In Step ST2, the controller 2 may control the bias power supply 32 to supply the electric bias EB to the bias electrode.

Next, Step ST3 is performed. In Step ST3, the film EF is etched. In Step ST3, Step STc, Step STe, and Step STf described above are performed. In Step ST3, at least one of Step STb, Step STd, or Step STg described above may be further performed. In addition, in Step ST3, the cycle CY described above may be repeated. By Step ST3, as illustrated in FIG. 7C, the pattern of the organic film OF is transferred to the film EF, and the recess is formed in the film EF.

Next, Step ST4 is performed. In Step ST4, the organic film OF is removed. In Step ST4, the plasma is generated from an ashing gas in the chamber 10 to remove the organic film OF. The ashing gas used in Step ST4 includes an oxygen-containing gas (for example, an oxygen gas and/or a CO gas).

In Step ST4, the controller 2 controls the gas supply 20 to supply the ashing gas into the chamber 10. In Step ST4, the controller 2 controls the gas exhaust system 40 to set the pressure in the chamber 10 to the designated pressure. In Step ST4, the controller 2 controls the radio frequency power supply 31 to supply the source radio frequency power RF to the radio frequency electrode to generate the plasma from the etching gas.

Next, Step ST5 is performed. In Step ST5, as illustrated in FIG. 7D, the film EF is further etched so that a depth of the recess increases. In Step ST5, Step STc, Step STe, and Step STf described above are performed. In Step ST5, at least one of Step STb, Step STd, or Step STg described above may be further performed. In addition, in Step ST5, the cycle CY described above may be repeated.

According to the method MTA, the mask MHM is protected by the deposit MDP during the etching of the film EF in Step ST3 and Step ST5. Therefore, the decrease in the mask MHM due to the etching of the film EF is suppressed. In addition, according to the method MTA, even when the pattern of the resist mask PR is shifted from the pattern of the mask MHM, it is possible to advance the etching of the film EF while suppressing the decrease in the mask MHM.

Hereinafter, an evaluation experiment performed for evaluation of the method MT and first to third comparative experiments will be described. In the evaluation experiment and the first to third comparative experiments, a sample substrate having a titanium nitride film was prepared. In the evaluation experiment, Step STc and Step STe were performed by using the plasma processing apparatus 1 to form the deposit on the titanium nitride film of the sample substrate. In the first and second comparative experiments, only Step STc was performed by using the plasma processing apparatus 1 to form the deposit on the titanium nitride film of the sample substrate. In the third comparative experiment, an attempt was made to perform only Step STe by using the plasma processing apparatus 1 to form the deposit on the titanium nitride film of the sample substrate. The conditions of each of the evaluation experiment and the first to third comparative experiments are illustrated below.

### Evaluation Experiment and Second and Third Comparative Experiments

Process gas: mixed gas of nitrogen gas, C₄F₈ gas, oxygen gas, and Ar gas
Source radio frequency power and bias radio frequency power in Step STc: 100 W and 0 W
Source radio frequency power and bias radio frequency power in Step STe: 30 W and 30 W

### First Comparative Experiment

Process gas: mixed gas of nitrogen gas, C₄F₈ gas, oxygen gas, and Ar gas
Source radio frequency power and bias radio frequency power in Step STc: 30 W and 0 W

In the evaluation experiment and the first to third comparative experiments, a proportion of the carbon-to-carbon bond in the deposit was measured by X-ray photoelectron spectroscopy (XPS). As a result, the proportions of the carbon-to-carbon bond in the deposit measured in the first and second comparative experiments and the evaluation experiment were 17.02%, 19.73%, and 29.83%. In the third comparative experiment, almost no deposit was formed. From this, it was confirmed that the deposit containing the carbon-to-carbon bond could be formed on the substrate at a high proportion by performing Step STc and Step STe.

Hereinafter, first to third evaluation experiments for evaluation of the method MTA and a comparative experiment performed will be described. In the first to third evaluation experiments and the comparative experiment, a sample substrate having the structure illustrated in FIG. 7A was prepared. In the sample substrate, the mask MHM was made of titanium nitride. In the first to third evaluation experiments and the comparative experiment, Steps ST1 to ST3 were applied to the sample substrate by using the plasma processing apparatus 1. However, in the comparative experiment, Step STe was not performed in Step ST3. The conditions of each of the first to third evaluation experiments and the comparative experiment are illustrated below.

### First to Third Evaluation Experiments and Comparative Experiment

Process gas: mixed gas of nitrogen gas, C₄F₈ gas, oxygen gas, and Ar gas
Source radio frequency power and bias radio frequency power in Step STb: 1000 W and 0 W
Source radio frequency power and bias radio frequency power in Step STc: 100 W and 0 W
Source radio frequency power of Step STe in each of first to third evaluation experiments: 30 W
Bias radio frequency power of Step STe in each of first to third evaluation experiments: 10 W, 30 W, and 50 W
Source radio frequency power and bias radio frequency power in Step STf: 30 W and 900 W

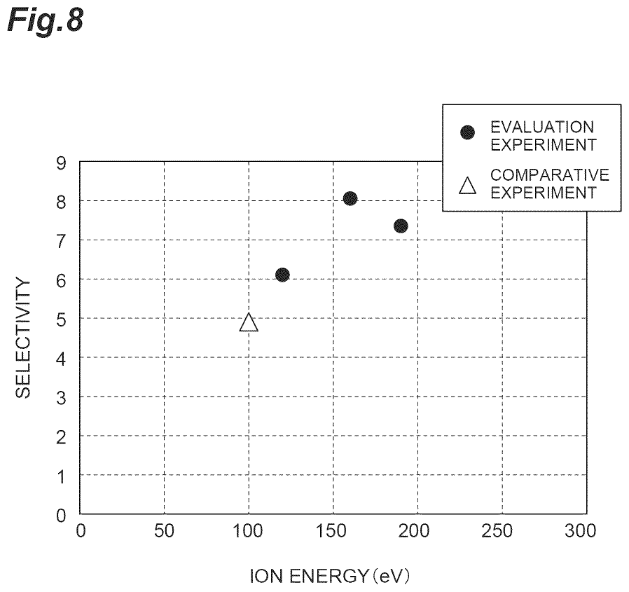

In the first to third evaluation experiments and the comparative experiment, etching selectivity of the film EF to the etching of the mask MHM was obtained. The selectivity is a value obtained by dividing an amount of decrease in a thickness of the mask MHM by the depth of the recess formed in the film EF. FIG. 8 illustrates results of the first to third evaluation experiments and the comparative experiment. FIG. 8 illustrates a relationship between the energy of the ions supplied to the substrate W in Step STe of each of the first to third evaluation experiments and the selectivity. In Step STe of the first to third evaluation experiments, the energies of the ions supplied to the substrate W were 120 eV, 160 eV, and 190 eV, respectively. FIG. 8 further illustrates a relationship between the energy of the ions supplied to the substrate W in Step STc of the comparative experiment and the selectivity. As illustrated in FIG. 8, considerably higher selectivity was obtained in the first to third evaluation experiments than in the comparative experiment. Therefore, it was confirmed that, when Step ST3 includes Step STc and Step STe, high selectivity could be obtained, that is, the decrease in the mask MHM due to the etching of the film EF was suppressed.

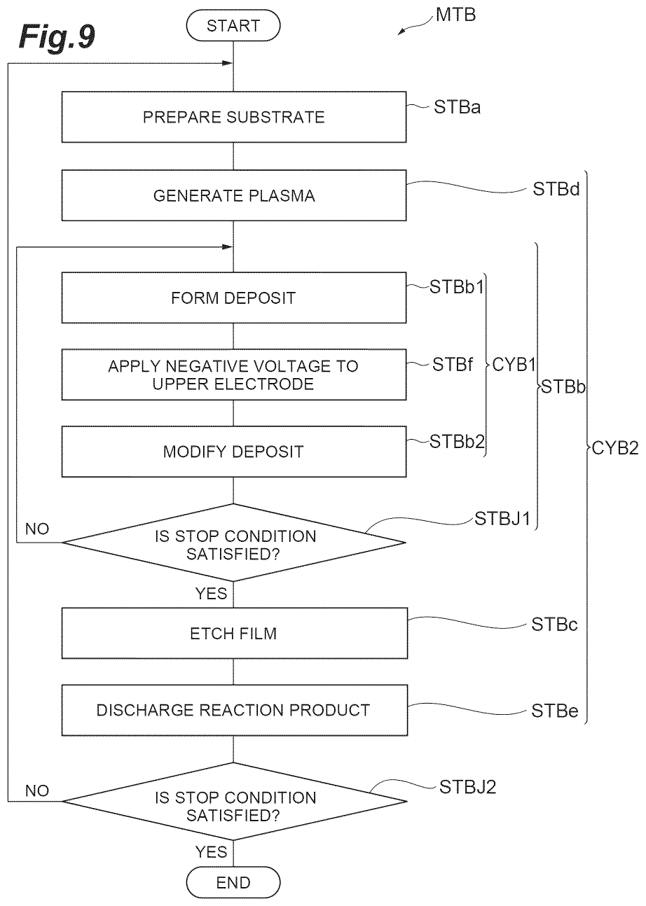

Hereinafter, an etching method according to still another example embodiment will be described with reference to FIG. 9. FIG. 9 is a flowchart illustrating the etching method according to still another example embodiment. The etching method illustrated in FIG. 9 (hereinafter, referred to as a “method MTB”) is performed in the plasma processing apparatus to etch the dielectric film of a substrate. The plasma processing apparatus used in the method MTB may be the plasma processing apparatus 1.

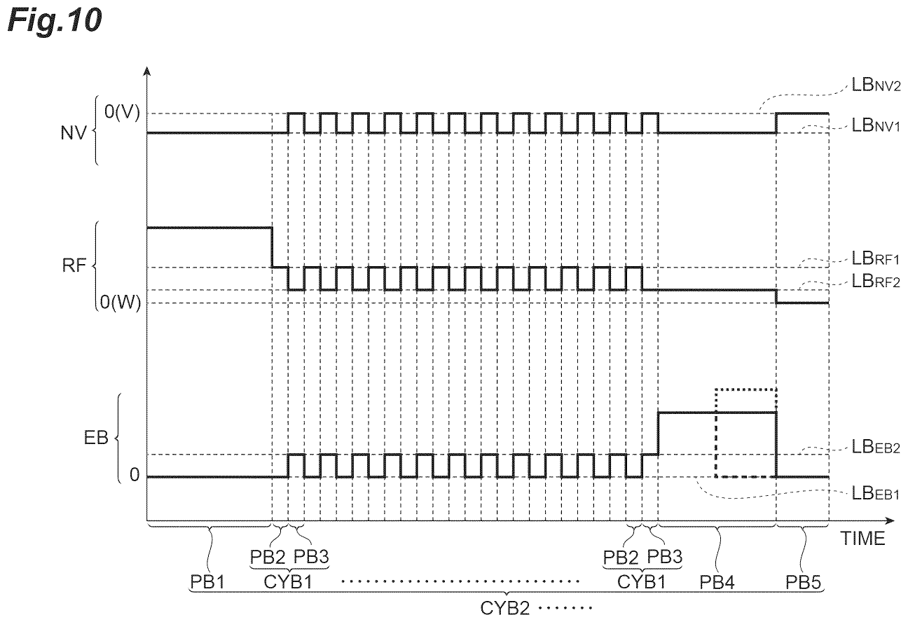

Hereinafter, FIG. 10 will be referred to along with FIG. 9. FIG. 10 is a timing chart related to the plasma processing apparatus according to an example embodiment. The controller 2 executes first control of repeating a first cycle CYB1.

The first cycle CYB1 is performed in a state where the process gas having the deposit property is supplied into the chamber 10. The process gas having the deposit property will be described later. In the first cycle CYB1, the controller 2 controls the radio frequency power supply 31 and the bias power supply 32 to change at least one of the power level of the source radio frequency power RF or the level of the electric bias to two different levels in sequence. In addition, in the first cycle CYB1, the controller 2 may control the power supply 35 to change the level (absolute value of the voltage level) of the negative voltage NV applied to the upper electrode to two different levels in sequence.

In an embodiment, in the first cycle CYB1, each of the power level of the source radio frequency power RF and the level of the electric bias may be changed to two different levels in sequence. For example, in the first cycle CYB1, the power level of the source radio frequency power RF may be changed to a power level LB_{RF1} and a power level LB_{RF2} in sequence, and the level of the electric bias EB may be changed to a level LB_{EB1} and a level LB_{EB2} in sequence. LB_{RF1} is higher than LB_{RF2}, and LB_{EB2} is higher than LB_{EB1}. In addition, in the first cycle CYB1, the level (absolute value of the voltage level) of the negative voltage NV may be changed to the level LB_{NV1} and the level LB_{NV2} in sequence. The level LB_{NV1} is higher than the level LB_{NV2}.

The change in the power level of the source radio frequency power RF and the change in the level of the electric bias in the first cycle CYB1 may be synchronized with each other. For example, a period during which the power level of the source radio frequency power RF is the power level LB_{RF1} and a period during which the level of the electric bias EB is the level LB_{EB1} may be synchronized with each other. Further, a period during which the power level of the source radio frequency power RF is the power level LB_{RF2} and a period during which the level of the electric bias EB is the level LB_{EB2} may be synchronized with each other.

In addition, the change in the level of the negative voltage NV in the first cycle CYB1 may be synchronized with the change in the power level of the source radio frequency power RF. For example, a period during which the power level of the source radio frequency power RF is the power level LB_{RF1} and a period during which the level of the negative voltage NV is the level LB_{NV1} may be synchronized with each other. For example, a period during which the power level of the source radio frequency power RF is the power level LB_{RF2} and a period during which the level of the negative voltage NV is the level LB_{NV2} may be synchronized with each other.

A repetition frequency of the first cycle CYB1 may be 1 Hz or higher and 50 kHz or lower. The repetition frequency of the first cycle CYB1 may be 100 Hz or higher or may be 21 kHz or lower. In addition, the power level of the source radio frequency power RF may be a power level in a range of 0 W or 7 W or higher and 3000 W or lower. In addition, when the electric bias EB is the bias radio frequency power, the power level of the bias radio frequency power may be a power level in a range of 0 W or 7 W or higher and 3000 W or lower.

In addition, the controller 2 executes second control after the first control, that is, after the repetition of the first cycle. In the second control, the controller 2 controls the radio frequency power supply 31 and the bias power supply 32 to supply the source radio frequency power RF and the electric bias EB to generate the plasma of the etching gas in the chamber 10. In the second control, the power level of the source radio frequency power RF may be set to a power level in a range of 7 W or higher and 3000 W or lower. In addition, when the electric bias EB is the bias radio frequency power, in the second control, the power level of the bias radio frequency power may be set to a power level in a range of 7 W or higher and 3000 W or lower. In the second control, the level of the electric bias EB may be constant. Alternatively, in the second control, the level of the electric bias EB may increase stepwise or continuously. Alternatively, in the second control, the level of the electric bias EB may decrease stepwise or continuously.

In addition, the controller 2 executes third control of repeating a second cycle CYB2 including the first control and the second control. A repetition frequency of the second cycle CYB2 is lower than the repetition frequency of the first cycle CYB1. The repetition frequency of the second cycle CYB2 may be 1 Hz or higher and 50 kHz or lower. The repetition frequency of the second cycle CYB2 may be 10 Hz or higher or may be 2.1 kHz or lower. A repetition frequency of the second control is the same as the repetition frequency of the second cycle CYB2.

The second cycle CYB2 may further include fourth control performed before the first control. In the fourth control, the controller 2 controls the radio frequency power supply 31 to supply the source radio frequency power RF to generate the plasma from the process gas. The power level of the source radio frequency power RF in the fourth control may be higher than the power level of the source radio frequency power RF used in the repetition of the first cycle CYB1. The fourth control may be included in the first cycle CYB1, or may be performed before control corresponding to Step STBb1, which will be described later, in the first cycle CYB1.

In addition, the second cycle CYB2 may further include fifth control performed after the second control. In the fifth control, the controller 2 controls the radio frequency power supply 31 and the bias power supply 32 to stop the supply of the source radio frequency power RF and the supply of the electric bias EB. In the fifth control, the controller 2 may control the gas exhaust system 40 to discharge the reaction product from the chamber 10.

In addition, the second cycle CYB2 may include sixth control instead of the fifth control or in addition to the fifth control. In the sixth control, the controller 2 controls the radio frequency power supply 31 and the bias power supply 32 to stop the supply of the electric bias EB in a state where the source radio frequency power RF is supplied. The sixth control may be performed at least any one of before or after the second control.

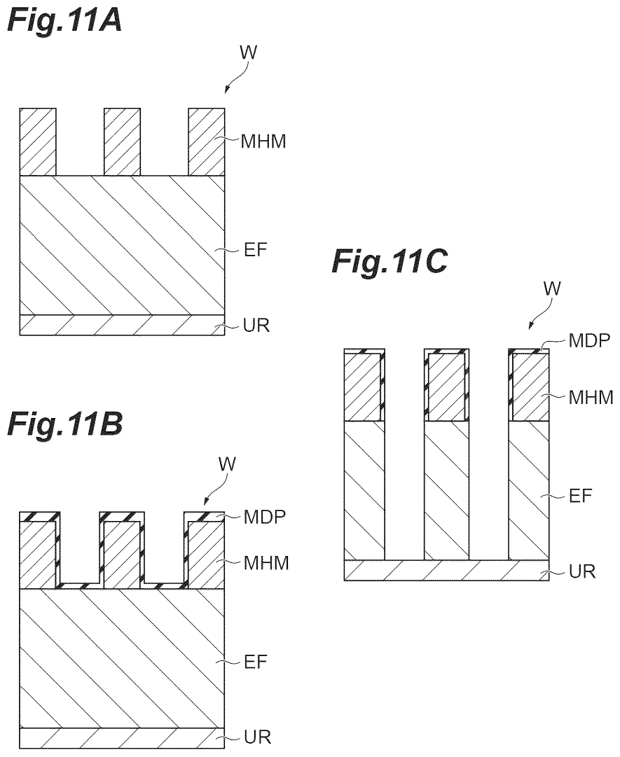

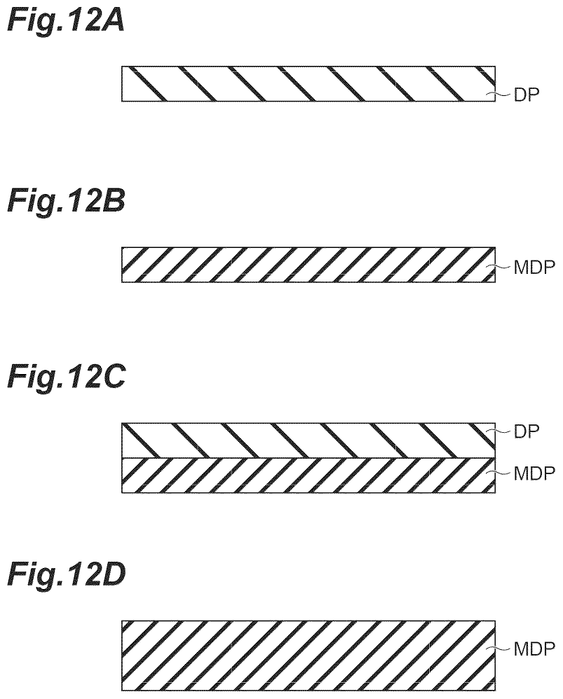

Hereinafter, the method MTB will be described with reference to FIG. 11A to FIG. 11C and FIG. 12A to FIG. 12D, as well as FIGS. 9 and 10. In addition, the control of each part of the plasma processing apparatus 1 via the controller 2 will also be described. Each of FIG. 11A to FIG. 11C is a partially enlarged cross-sectional view illustrating an example of a substrate related to each step of the etching method according to still another example embodiment. Each of FIG. 12A to FIG. 12D is a view illustrating a deposit grown in the etching method according to still another example embodiment. Hereinafter, the method MTB will be described with a case where the plasma processing apparatus 1 is used as an example. The method MTB may be performed by using a plasma processing apparatus different from the plasma processing apparatus 1.

As illustrated in FIG. 9, the method MTB includes Step STBa, Step STBb, and Step STBc. The method MTB may further include at least one of Step STBd or Step STBe.

In Step STBa, the substrate W is prepared on the substrate support 11 in the chamber 10 of the plasma processing apparatus 1. The steps of the method MTB performed after Step STBa are performed in a state where the substrate W is placed on the substrate support 11.

As illustrated in FIG. 11A, the substrate W to which the method MTB is applied includes a film EF and a mask MHM. The substrate W may further include an underlying region UR. The film EF is a film to be etched in the method MTB. The film EF is provided on the underlying region UR. The film EF may be a silicon-containing film or a carbon-containing film. The film EF may be a dielectric film containing silicon and oxygen. The film EF may be a low dielectric constant film, such as a SiOC film or a SiOCH film. Alternatively, the film EF may be an organic film. The mask MHM is provided on the film EF. The mask MHM has a pattern transferred to the film EF by etching. That is, the mask MHM is provided with one or more openings. The mask MHM may be a metal hard mask. The mask MHM may be made of titanium (for example, titanium nitride), tungsten, molybdenum, or ruthenium. The mask MHM may be made of another metal-containing material. The surface of the mask MHM may be exposed or may be covered with the organic film. Alternatively, the mask MHM may be a resist mask, such as an EUV resist mask or an ArF resist mask.

Step STBd is performed after Step STBa and before Step STBb. Step STBd is performed in a period PB1 (see FIG. 10). In Step STBd, the plasma is generated from a process gas in the chamber 10. The process gas is a gas having a deposit property. The process gas includes a fluorine-containing gas. The process gas may contain a gas component containing fluorine and carbon. This gas component may be a fluorocarbon gas, such as a C₄F₈ gas. That is, the fluorine-containing gas may be a fluorocarbon gas. In addition, this gas component may contain a hydrofluorocarbon gas in addition to the fluorocarbon gas or instead of the fluorocarbon gas. The process gas may further contain one or more of a nitrogen gas, an oxygen-containing gas (for example, an oxygen gas), and a noble gas (for example, an Ar gas). In Step STBd, the plasma is ignited in the chamber 10, and radicals are generated from the gas component of the process gas.

In Step STBd, the controller 2 controls the gas supply 20 to supply the process gas into the chamber 10. In Step STBd, the controller 2 controls the gas exhaust system 40 to set the pressure in the chamber 10 to the designated pressure. In Step STBd, the controller 2 controls the radio frequency power supply 31 to supply the source radio frequency power RF to the radio frequency electrode to generate the plasma from the process gas. In an embodiment, the power level of the source radio frequency power RF used in Step STBd may be higher than the power level of the source radio frequency power RF used in Step STBb and Step STBc described later. In Step STBd, the controller 2 may control the bias power supply 32 not to supply the electric bias EB to the bias electrode. Alternatively, in Step STBd, the controller 2 may control the bias power supply 32 to supply the electric bias EB to the bias electrode.

Next, in the method MTB, Step STBb is performed. In an embodiment, Step STBb is performed after Step STBd. In Step STBb, the first cycle CYB1 is repeated. The first cycle CYB1 includes Step STBb1 and Step STBb2. The first cycle CYB1 may further include Step STBf.

Step STBb1 is performed in a period PB2 (see FIG. 10). In addition, Step STBb2 is performed in a period PB3 (see FIG. 10). The period PB3 is a period following the period PB2. In Step STBb1, the deposit DP is formed on the substrate W (see FIG. 12A). The deposit DP is supplied from the plasma generated from the above-described process gas in the chamber 10. That is, the process gas used in Step STBd may be the same as the process gas used in Step STBb1. The deposit DP may contain carbon and fluorine.

In Step STBb1, the controller 2 controls the gas supply 20 to supply the process gas into the chamber 10. In Step STBb1, the controller 2 controls the gas exhaust system 40 to set the pressure in the chamber 10 to the designated pressure. In Step STBb1, the controller 2 controls the radio frequency power supply 31 to supply the source radio frequency power RF to the radio frequency electrode to generate the plasma from the process gas. In an embodiment, the power level (power level LB_{RF1} or S2) of the source radio frequency power RF used in Step STBb1 may be lower than the power level (power level S1) of the source radio frequency power RF used in Step STBd. In Step STBb1, the controller 2 may control the bias power supply 32 not to supply the electric bias EB to the bias electrode. Alternatively, in Step STBb1, the controller 2 may control the bias power supply 32 to supply the electric bias EB to the bias electrode.

Step STBf may be performed at least in parallel with Step STBb1. That is, Step STBf may be performed at least in the period PB2. In Step STBf, the negative voltage NV is applied to the upper electrode. In Step STBf, the positive ions are attracted to the ceiling plate 13p from the plasma in the chamber 10. As a result, a substance (for example, silicon) forming the ceiling plate 13p is released. The substance released from the ceiling plate 13p is bonded to the fluorine chemical species in the plasma, to decrease an amount of the fluorine chemical species in the plasma.

In Step STBf, the controller 2 controls the power supply 35 to apply the negative voltage NV to the upper electrode. Step STBf may be performed in the period PB1 in addition to the period PB2. In addition, the negative voltage NV may be applied to the upper electrode even in a period PB4 described later.

In Step STBb2, the deposit DP is modified by supplying the ions from the plasma to the deposit DP. In Step STBb2, as illustrated in FIG. 12B, the deposit MDP is generated from the deposit DP. The process gas used in Step STBb2 may be the same process gas as the process gas used in Step STBb1. That is, in Step STBb2, the plasma may be generated from the above-described process gas having the deposit property. In Step STBb2, the energy of the ions supplied from the plasma to the deposit DP is higher than the energy of the ions supplied from the plasma to the substrate W in Step STBb1. In Step STBb2, the ions having relatively high energy are supplied to the deposit DP, and unnecessary elements (for example, fluorine) are extracted from the deposit DP. Therefore, in the deposit MDP obtained in Step STBb2, many bonds having high binding energy (for example, carbon-to-carbon bond) may be formed.

In Step STBb2, the controller 2 controls the gas supply 20 to supply the process gas into the chamber 10. In Step STBb2, the controller 2 controls the gas exhaust system 40 to set the pressure in the chamber 10 to the designated pressure. In Step STBb2, the controller 2 controls the radio frequency power supply 31 to supply the source radio frequency power RF to the radio frequency electrode to generate the plasma from the process gas. In an embodiment, the power level (power level LB_{RF2} or S3) of the source radio frequency power RF used in Step STBb2 may be lower than the power level (power level S1) of the source radio frequency power RF used in Step STBd. In an embodiment, the power level of the source radio frequency power RF (power level LB_{RF2} or S3) used in Step STBb2 may be equal to or lower than the power level of the source radio frequency power RF (power level LB_{RF1} or S2) used in Step STBb1, or may be lower than the power level of the source radio frequency power RF (power level LB_{RF1} or S2) used in Step STBb1. In Step STBb2, the controller 2 controls the bias power supply 32 to supply the electric bias EB to the bias electrode. In an embodiment, the level of the electric bias EB used in Step STBb2 may be higher than the level of the electric bias EB used in Step STBb1. In an embodiment, the level of the electric bias EB used in Step STBb2 may be higher than the level of the electric bias EB used in Step STBd. As described above, the supply of the electric bias EB may be stopped in at least one of Step STBd or Step STBb1.

In the repetition of the first cycle CYB1 in Step STBb, as illustrated in FIG. 12C, the deposit DP is formed on the deposit MDP, and as illustrated in of FIG. 12D, the deposit DP is modified, and the thickness of the deposit MDP increases.

Next, in the method MTB, Step STBJ1 is performed. In Step STBJ1, it is determined whether or not a stop condition is satisfied. In Step STBJ1, the stop condition is satisfied when the number of times at which the first cycle CYB1 is executed reaches a predetermined number of times. When it is determined that the stop condition is not satisfied in Step STBJ1, the first cycle CYB1 is performed again. When it is determined that the stop condition is satisfied in Step STBJ1, the repetition of the first cycle CYB1 ends. As a result of repeating the first cycle CYB1, a surface of the substrate W is covered with the deposit MDP as illustrated in FIG. 11B.

Next, in the method MTB, Step STBc is performed. Step STBc is performed after the repetition of the first cycle CYB1. Step STBc is performed in the period PB4 (see FIG. 10). The period PB4 is a period after the alternate repetition of the periods PB2 and PB3 or following the alternate repetition of the periods PB2 and PB3.

In Step STBc, the film EF is etched by using a plasma generated from an etching gas in the chamber 10. In Step STBc, the plasma may be generated from the above-described process gas. That is, in Step STBc, the same process gas as the process gas used in Step STBb1 and Step STBb2 may be used as the etching gas. Alternatively, the etching gas used in Step STBc may be another gas selected to selectively etch the film EF.

In Step STBc, the controller 2 controls the gas supply 20 to supply the etching gas into the chamber 10. In Step STBc, the controller 2 controls the gas exhaust system 40 to set the pressure in the chamber 10 to the designated pressure. In Step STBc, the controller 2 controls the radio frequency power supply 31 to supply the source radio frequency power RF to the radio frequency electrode to generate the plasma from the etching gas. In an embodiment, the power level (power level S4) of the source radio frequency power RF used in Step STBc may be lower than the power level (power level S1) of the source radio frequency power RF used in Step STBd. In an embodiment, the power level (power level S4) of the source radio frequency power RF used in Step STBc may be lower than the power level (power level LB_{RF1} or S2) of the source radio frequency power RF used in Step STBb1. In addition, the power level (power level S4) of the source radio frequency power RF used in Step STBc may be the same as or substantially the same as the power level (power level LB_{RF2} or S3) of the source radio frequency power RF used in Step STBb2. In Step STBc, the controller 2 controls the bias power supply 32 to supply the electric bias EB to the bias electrode. In an embodiment, the level (level B4) of the electric bias EB used in Step STBc may be higher than the level (level LB_{EB2} or B3) of the electric bias EB used in Step STBb2.

In Step STBc, the level of the electric bias EB may be constant (see the level of the electric bias EB in the period PB4 indicated by a solid line in FIG. 10). Alternatively, in Step STBc, the level of the electric bias EB may increase stepwise or continuously (see a temporal change from the level of the electric bias EB in the period PB4 indicated by a dotted line to the level of the electric bias EB in the period PB4 indicated by a solid line in FIG. 10). Alternatively, in Step STBc, the level of the electric bias EB may decrease stepwise or continuously.

In the method MTB, the second cycle CYB2 including Step STBb and Step STBc is repeated. The second cycle CYB2 may further include Step STBd. Step STBd may be included in the first cycle CYB1, or may be performed before Step STBb1 in the first cycle CYB1.

In an embodiment, the second cycle CYB2 may further include Step STBe. Step STBe is performed after Step STBc. Step STBe is performed in a period PB5 (see FIG. 10). The period PB5 is a period after the period PB4 or following the period PB4.

In Step STBe, the reaction product generated in Step STBc is discharged from the chamber 10. In Step STBe, the plasma need not be generated in the chamber 10.

In Step STBe, the controller 2 controls the gas exhaust system 40 to perform the exhaust of the chamber 10 to discharge the reaction product from the chamber 10. In Step STBe, the controller 2 may control the radio frequency power supply 31 to stop the supply of the source radio frequency power RF. In Step STBe, the controller 2 may control the bias power supply 32 to stop the supply of the electric bias EB.

In an embodiment, the second cycle CYB2 may include Step STBg instead of Step STBe or in addition to Step STBe. In Step STBg, the supply of the electric bias EB is stopped in a state where the source radio frequency power RF is supplied (see the level of the electric bias EB in the period PB4 indicated by a broken line in FIG. 10). Step STBg may be performed at least any one of before or after Step STBc.

The method MTB further includes Step STBJ2. In Step STBJ2, it is determined whether or not a stop condition is satisfied. In Step STBJ2, the stop condition is satisfied when the number of times at which the second cycle CYB2 is executed reaches a predetermined number of times. When it is determined that the stop condition is not satisfied in Step STBJ2, the second cycle CYB2 is performed again. When it is determined that the stop condition is satisfied in Step STBJ2, the method MTB ends. In the method MTB, as illustrated in FIG. 11C, the recess is formed in the film EF as a result of repeating the second cycle CYB2.

In the method MTB, as a result of repeating Step STBb1 and Step STBb2, the thickness of the deposit MDP increases, and the modified deposit MDP having an interatomic bond having high binding energy over an entire thickness direction is formed. The mask MHM is protected by the deposit MDP from the etching of Step STBc. Therefore, according to the method MTB, the decrease in the mask MHM due to etching is suppressed.

In the method MTB, the gas condition and/or the temperature condition in each step of the second cycle CYB2 may be changed in accordance with the progress of the repetition of the second cycle CYB2, that is, in accordance with the increase in the depth of the recess formed in the film EF.

In addition, with the progress of the repetition of the first cycle CYB1, at least one of the power level of the source radio frequency power RF or the level of the electric bias EB may be changed in each step of the first cycle CYB1. For example, the first cycle CYB1 may be repeated by setting at least one level of the power level of the source radio frequency power RF or the level of the electric bias EB in each step, to a relatively low level. Thereafter, the first cycle CYB1 may be repeated by setting the at least one level to a relatively high level.

Hereinafter, the method MTA when some steps of the method MTB are performed will be described again with reference to FIG. 6 and FIG. 7A to FIG. 7D. In the substrate W to which the method MTA described below is applied, the mask MHM is the above-described metal hard mask.

In Step STa of the method MTA, as in Step STBa of the method MTB, the substrate W (see FIG. 7A) is prepared on the substrate support 11 in the chamber 10 of the plasma processing apparatus 1. The steps of the method MTA performed after Step STa are performed in a state where the substrate W is placed on the substrate support 11. After Step STa, Step ST1 to Step ST2 are performed as described above.

Next, Step ST3 is performed. In Step ST3, the film EF is etched. In Step ST3, Step STBb and Step SBTc described above are performed. In Step ST3, at least one of Step STBd, Step STBe, Step STBf, or Step STBg described above may be further performed. In an embodiment, in Step ST3, the repetition of the first cycle CYB1 may be performed, or the repetition of the second cycle CYB2 may be performed. By Step ST3, as illustrated in FIG. 7C, the pattern of the organic film OF is transferred to the film EF, and the recess is formed in the film EF. Next, as described above, Step ST4 is performed.

Next, Step ST5 is performed. In Step ST5, as illustrated in FIG. 7D, the film EF is further etched so that the depth of the recess increases. In Step ST5, Step STBb and Step STBc described above are performed. In Step ST5, at least one of Step STBd, Step STBe, Step STBf, or Step STBg described above may be further performed. In an embodiment, in Step ST5, the repetition of the first cycle CYB1 may be performed, or the repetition of the second cycle CYB2 may be performed.

In Step STBc performed in the method MTA, the level of the electric bias EB may increase stepwise or continuously as described above. In this case, since the etching of the film EF in Step STBc includes the etching with low energy ions, it is possible to suppress the damage to the mask MHM during the etching of the film EF and to suppress the clogging of the recess in the organic film OF. Therefore, in the next first cycle CYB1, the protection of the mask MHM via the deposit MDP can be promoted. Therefore, it is possible to improve the etching selectivity of the film EF with respect to the mask MHM.

Alternatively, in Step STBc performed in the method MTA, the level of the electric bias EB may decrease stepwise or continuously as described above. In this case, since the total amount of the energy of the ions used for the etching of the film EF in Step STBc is suppressed, it is possible to suppress the damage to the mask MHM during the etching of the film EF and to suppress the clogging of the recess in the organic film OF. Therefore, in the next first cycle CYB1, the protection of the mask MHM via the deposit MDP can be promoted. Therefore, it is possible to improve the etching selectivity of the film EF with respect to the mask MHM.

Hereinafter, fourth and fifth evaluation experiments performed for evaluation of the method MTB will be described. In the fourth and fifth evaluation experiments, a sample substrate having the structure illustrated in FIG. 7A was prepared. In the sample substrate, the mask MHM was made of titanium nitride. In the fourth and fifth evaluation experiments, Steps ST1 to ST3 were applied to the sample substrate by using the plasma processing apparatus 1. In the fourth evaluation experiment, the bias level in the period PB4 was constant, and in the fifth evaluation experiment, the period PB4 was divided into two stages, and the bias level increased stepwise. The conditions of each of the fourth and fifth evaluation experiments are illustrated below.

### Conditions of Fourth and Fifth Evaluation Experiments

Process gas: mixed gas of nitrogen gas, hydrogen gas, Ar gas, CF₄ gas, and C+F₈ gas
Source radio frequency power of Step STBb1 of each of fourth and fifth evaluation experiments: 30 W
Bias radio frequency power of Step STBb2 of each of fourth and fifth evaluation experiments: 30 W
Repetition frequency of Step STBb1 and Step STBb2 in fourth and fifth evaluation experiments: 625 Hz
Source radio frequency power in Step STBc of fourth and fifth evaluation experiments: 30 W
Bias radio frequency power of Step STBc of fourth evaluation experiment: 700 W
Bias radio frequency power in Step STBc of fifth evaluation experiment: increase stepwise from 200 W to 700 W

In the fourth and fifth evaluation experiments, the etching selectivity of the film EF to the etching of the mask MHM was obtained. The selectivity is a value obtained by dividing the amount of decrease in a thickness of the mask MHM by the depth of the recess formed in the film EF. As a result, in the fourth evaluation experiment, the selectivity was 21.0, and in the fifth evaluation experiment, the selectivity was 25.3. In addition, a width of the recess at the top portion of the organic film OF was 6.7 nm in the fourth evaluation experiment and 7.3 nm in the fifth evaluation experiment. As described above, high selectivity was obtained in both the fourth and fifth evaluation experiments. In addition, in the fifth evaluation experiment, the width of the recess in the organic film OF was larger and the selectivity was higher than in the fourth evaluation experiment. Therefore, it was confirmed that, by increasing the level of the electric bias stepwise in Step STBc to increase the energy of the ions stepwise, the clogging of the recess in the organic film OF could be suppressed, and the selectivity could be improved.

While various example embodiments have been described above, various additions, omissions, substitutions and changes may be made without being limited to the example embodiments described above. Elements of the different embodiments may be combined to form another embodiment.

For example, the level of the negative voltage NV may be constant in the first cycle CYB1. Further, the level of the negative voltage NV may be constant in the second cycle CYB2.

In the following, various example embodiments included in the disclosure is described in [E1] to [E19], [F1] to [F14] and [G1] to [G20].
[E1] An etching method including:
(a) preparing a substrate on a substrate support in a chamber of a plasma processing apparatus, the substrate including a dielectric film containing silicon and oxygen and a metal hard mask provided on the dielectric film;
(b) forming a deposit on the substrate, the deposit being supplied from a plasma generated from a process gas containing a gas component containing fluorine and carbon in the chamber;
(c) supplying ions from a plasma generated from the process gas to the deposit to modify the deposit; and
(d) etching the dielectric film by using a plasma generated in the chamber after the (c), wherein
a power level of a source radio frequency power used to generate the plasma from the process gas in the (c) is equal to or lower than a power level of the source radio frequency power used to generate the plasma from the process gas in the (b),
a level of an electric bias supplied to the substrate support in the (c) is higher than a level of the electric bias supplied to the substrate support in the (b), or the electric bias is not supplied to the substrate support in the (b), and
a level of the electric bias supplied to the substrate support in the (d) is higher than the level of the electric bias supplied to the substrate support in the (c).
[E2] The etching method according to E1, wherein energy of the ions supplied to the deposit in the (c) is higher than energy of ions supplied to the substrate in the (b).
[E3] The etching method according to E1 or E2, wherein the process gas used in the (b) and the (c) is used to generate the plasma used in the (d).
[E4] The etching method according to any one of E1 to E3, further including:
(e) generating a plasma from the process gas in the chamber after the (a) and before the (b),
wherein a power level of the source radio frequency power used to generate the plasma from the process gas in the (e) is higher than the power level of the source radio frequency power used to generate the plasma from the process gas in each of the (b) and the (c).
[E5] The etching method according to any one of E1 to E3, wherein a cycle including (b), (c), and (d) is repeated.
[E6] The etching method according to E5, wherein
the cycle further includes (e) generating a plasma from the process gas in the chamber before the (b), and
a power level of the source radio frequency power used to generate the plasma from the process gas in the (e) is higher than the power level of the source radio frequency power used to generate the plasma from the process gas in each of the (b) and the (c).
[E7] The etching method according to E5, wherein
the cycle further includes (f) discharging a reaction product generated in the (d) from the chamber after the (d), and
the plasma is not generated in the chamber in the (f).
[E8] The etching method according to any one of E1 to E7, wherein the metal hard mask contains at least one metal selected from the group consisting of titanium, tungsten, molybdenum, and ruthenium.
[E9] A plasma processing apparatus including:
a chamber;
a substrate support provided in the chamber;
a gas supply configured to supply a gas into the chamber;
a radio frequency power supply configured to supply a source radio frequency power to generate a plasma in the chamber;
a bias power supply configured to supply an electric bias to the substrate support; and
a controller configured to control the gas supply, the radio frequency power supply, and the bias power supply, wherein
the controller is configured to, in a state where a substrate including a dielectric film containing silicon and oxygen and a metal hard mask on the dielectric film is placed on the substrate support,
   control the gas supply and the radio frequency power supply to generate a plasma from a process gas containing a gas component containing fluorine and carbon in the chamber to form a deposit on the substrate in a first operation,
   control the gas supply, the radio frequency power supply, and the bias power supply to supply ions from a plasma generated from the process gas to the deposit to modify the deposit in a second operation, and
   control the gas supply, the radio frequency power supply, and the bias power supply to etch the dielectric film by using a plasma generated in the chamber in a third operation after the deposit has been modified, and
the controller is configured to
   set a power level of the source radio frequency power used to generate the plasma from the process gas in the second operation to a level equal to or lower than a power level of the source radio frequency power used to generate the plasma from the process gas in the first operation,
   set a level of the electric bias supplied to the substrate support in the second operation to a level higher than a level of the electric bias supplied to the substrate support in the first operation, or not supply the electric bias to the substrate support in the first operation, and
   set a level of the electric bias supplied to the substrate support in the third operation to a level higher than the level of the electric bias supplied to the substrate support in the second operation.
[E10] An etching method including:
(a) preparing a substrate on a substrate support in a chamber of a plasma processing apparatus, the substrate including a film and a mask provided on the film;
(b) repeating a first cycle including
   (b1) forming a deposit on the substrate, the deposit being supplied to the substrate from a plasma generated from a process gas having a deposit property in the chamber, and
   (b2) supplying ions from a plasma to the deposit to modify the deposit; and
(c) etching the film by using a plasma generated in the chamber, wherein
a second cycle including the (b) and the (c) is repeated,
a power level of a source radio frequency power used to generate the plasma in a period during which the (b1) is performed in the first cycle is higher than a power level of the source radio frequency power in a period during which the (b2) is performed in the first cycle,
a level of an electric bias supplied to the substrate support to attract the ions into the substrate in the period during which the (b2) is performed in the first cycle is higher than a level of the electric bias supplied to the substrate support in the period during which the (b1) is performed in the first cycle, or the electric bias is not supplied to the substrate support in the (b1), and
a level of the electric bias supplied to the substrate support in the (c) is higher than the level of the electric bias supplied to the substrate support in the (b2).
[E11] The etching method according to E10, wherein energy of the ions supplied to the deposit in the (b2) is higher than energy of ions supplied to the substrate in the (b1).
[E12] The etching method according to E10 or E11, wherein the second cycle further includes (d) generating a plasma from the process gas in the chamber before the (b).
[E13] The etching method according to E12, wherein a power level of the source radio frequency power supplied to generate the plasma from the process gas in the chamber in the (d) is higher than the power level of the source radio frequency power used in the first cycle.
[E14] The etching method according to E10 or E11, wherein the first cycle further includes (d) generating the plasma from the process gas in the chamber before the (b1).
[E15] The etching method according to any one of E10 to E14, wherein
the second cycle further includes (e) discharging a reaction product generated in the (c) from the chamber after the (c), and
the plasma is not generated in the chamber in the (e).
[E16] The etching method according to any one of E10 to E14, wherein
the second cycle further includes (g) stopping supply of the electric bias for attracting the ions into the substrate in a state where the source radio frequency power for generating the plasma in the chamber is supplied, and
the (g) is performed at least any one of before or after the (c).
[E17] The etching method according to any one of E10 to E16, wherein the plasma generated in the (b2) is generated from a process gas that is the same as the process gas used in the (b1).
[E18] The etching method according to any one of E10 to E17, wherein the plasma generated in the (c) is generated from a process gas that is the same as the process gas used in the (b1).
[E19] The etching method according to any one of E10 to E18, wherein the level of the electric bias supplied to the substrate support in the (c) increases stepwise or continuously.
[F1] An etching method including:
(a) preparing a substrate on a substrate support in a chamber of a plasma processing apparatus, the substrate including a dielectric film containing silicon and oxygen and a metal hard mask provided on the dielectric film;
(b) forming a deposit on the substrate, the deposit being supplied from a plasma generated from a process gas containing a gas component containing fluorine and carbon in the chamber;
(c) supplying ions from a plasma generated from the process gas to the deposit to modify the deposit; and
(d) etching the dielectric film by using a plasma generated in the chamber after the (c),
wherein energy of the ions supplied to the deposit in the (c) is higher than energy of ions supplied to the substrate in the (b).

In the embodiment of [F1], the deposit containing carbon and fluorine is formed on the substrate in Step (b). In Step (c), the ions having relatively high energy are supplied to the deposit from the plasma generated from the same process gas as the process gas used in Step (b), and the deposit is modified. In Step (c), a large number of carbon-to-carbon bonds having high binding energy may be formed in the deposit. The metal hard mask is protected by the modified deposit from the etching of Step (d). Therefore, according to the embodiment of [F1], it is possible to suppress the decrease in the metal hard mask due to the etching.
[F2] The etching method according to F1, wherein the process gas used in the (b) and the (c) is used to generate the plasma used in the (d).
[F3] The etching method according to F1 or F2, further including:
(e) generating a plasma from the process gas in the chamber after the (a) and before the (b),
wherein a power level of a source radio frequency power used to generate the plasma from the process gas in the (e) is higher than the power level of the source radio frequency power used to generate the plasma from the process gas in each of the (b) and the (c).
[F4] The etching method according to F1 or F2, wherein a cycle including (b), (c), and (d) is repeated.
[F5] The etching method according to F4, wherein
the cycle further includes (e) generating a plasma from the process gas in the chamber before the (b), and
a power level of a source radio frequency power used to generate the plasma from the process gas in the (e) is higher than the power level of the source radio frequency power used to generate the plasma from the process gas in each of the (b) and the (c).
[F6] The etching method according to F4 or F5, wherein
the cycle further includes (f) discharging a reaction product generated in the (d) from the chamber after the (d), and
the plasma is not generated in the chamber in the (f).
[F7] The etching method according to any one of F1 to F6, wherein a level of an electric bias supplied to the substrate support in the (d) is higher than the level of the electric bias supplied to the substrate support in the (c).
[F8] The etching method according to any one of F1 to F7, wherein
a power level of a source radio frequency power used to generate the plasma from the process gas in the (c) is equal to or lower than a power level of the source radio frequency power used to generate the plasma from the process gas in the (b), and
a level of an electric bias supplied to the substrate support in the (c) is higher than a level of the electric bias supplied to the substrate support in the (b), or the electric bias is not supplied to the substrate support in the (b).
[F9] The etching method according to any one of F1 to F8, wherein
the plasma processing apparatus is a capacitively coupled plasma processing apparatus and includes an upper electrode disposed above the substrate support, and
the etching method further includes applying a negative voltage to the upper electrode when the (b) is performed.
[F10] The etching method according to F9, wherein
the upper electrode includes a ceiling plate defining an internal space of the chamber, and
the ceiling plate includes silicon.
[F11] The etching method according to any one of F1 to F10, wherein the gas component used in the (b) and the (c) includes a fluorocarbon.
[F12] The etching method according to any one of F1 to F11, wherein the metal hard mask is formed of titanium nitride.
[F13] The etching method according to any one of F1 to F12, wherein the dielectric film includes a low dielectric constant film.
[F14] A plasma processing apparatus including:
a chamber;
a substrate support provided in the chamber;
a gas supply configured to supply a gas into the chamber;
a radio frequency power supply configured to supply a source radio frequency power to generate a plasma in the chamber;
a bias power supply configured to supply an electric bias to the substrate support; and
a controller configured to control the gas supply, the radio frequency power supply, and the bias power supply, wherein
the controller is configured to, in a state where a substrate including a dielectric film containing silicon and oxygen and a metal hard mask on the dielectric film is placed on the substrate support,
   control the gas supply and the radio frequency power supply to generate a plasma from a process gas containing a gas component containing fluorine and carbon in the chamber to form a deposit on the substrate,
   control the gas supply, the radio frequency power supply, and the bias power supply to supply ions from the plasma generated from the process gas to the deposit to modify the deposit, and
   control the gas supply, the radio frequency power supply, and the bias power supply to etch the dielectric film by using a plasma generated in the chamber after the deposit was modified, and
the controller is configured to control the radio frequency power supply and/or the bias power supply to cause energy of the ions supplied to the deposit to modify the deposit to be higher than energy of ions supplied to the substrate to form the deposit on the substrate.
[G1] An etching method including:
(a) preparing a substrate on a substrate support in a chamber of a plasma processing apparatus, the substrate including a film and a mask provided on the film;
(b) repeating a first cycle including
   (b1) forming a deposit on the substrate, the deposit being supplied to the substrate from a plasma generated from a process gas having a deposit property in the chamber, and
(b2) supplying ions from a plasma to the deposit to modify the deposit; and
(c) etching the film by using a plasma generated in the chamber, wherein
a second cycle including the (b) and the (c) is repeated, and
energy of the ions supplied to the deposit in the (b2) is higher than energy of ions supplied to the substrate in the (b1)

In the embodiment of [G1], the deposit containing carbon and fluorine is formed on the substrate in Step (b1). In Step (b2), the ions having relatively high energy are supplied to the deposit, and the deposit is modified. As a result of repeating Step (b1) and Step (b2), the thickness of the deposit increases, and the modified deposit having an interatomic bond having a high binding energy over the entire deposit is formed. The mask is protected by the modified deposit from the etching of Step (c). Therefore, according to the embodiment of [G1], it is possible to suppress the decrease in the mask due to the etching.
[G2] The etching method according to G1, wherein the first cycle includes setting each of a power level a source radio frequency power for generating a plasma in the chamber and a level of an electric bias to attract ions into the substrate to two different levels in sequence.
[G3] The etching method according to G2, wherein
a power level of the source radio frequency power used to generate the plasma in a period during which the (b1) is performed in the first cycle is higher than a power level of the source radio frequency power in a period during which the (b2) is performed in the first cycle,
a level of the electric bias supplied to the substrate support to attract the ions into the substrate in the period during which the (b2) is performed in the first cycle is higher than a level of the electric bias supplied to the substrate support in the period during which the (b1) is performed in the first cycle.
[G4] The etching method according to any one of G1 to G3, wherein the second cycle further includes (d) generating a plasma from the process gas in the chamber before the (b).
[G5] The etching method according to G4, wherein a power level of a source radio frequency power supplied to generate the plasma from the process gas in the chamber in the (d) is higher than the power level of the source radio frequency power used in the first cycle.
[G6] The etching method according to any one of G1 to G3, wherein the first cycle further includes (d) generating the plasma from the process gas in the chamber before the (b1).
[G7] The etching method according to any one of G1 to G6, wherein
the plasma processing apparatus is a capacitively coupled plasma processing apparatus and includes an upper electrode disposed above the substrate support, and
the etching method further includes applying a negative voltage to the upper electrode when the (b1) is performed.
[G8] The etching method according to G7, wherein the negative voltage is not applied to the upper electrode when the (b2) is performed.
[G9] The etching method according to G5, wherein
the plasma processing apparatus is a capacitively coupled plasma processing apparatus and includes an upper electrode disposed above the substrate support, and
the etching method further includes applying a negative voltage to the upper electrode when the (d) is performed.
[G10] The etching method according to any one of G7 to G9, wherein
the upper electrode includes a ceiling plate defining an internal space of the chamber, and
the ceiling plate includes silicon.
[G11] The etching method according to any one of G1 to G10, wherein
the second cycle further includes (e) discharging a reaction product generated in the (c) from the chamber after the (c), and
the plasma is not generated in the chamber in the (e).
[G12] The etching method according to any one of G1 to G10, wherein
the second cycle further includes (g) stopping supply of an electric bias for attracting ions into the substrate in a state where a source radio frequency power for generating a plasma in the chamber is supplied, and
the (g) is performed at least any one of before or after the (c).
[G13] The etching method according to any one of G1 to G12, wherein the plasma generated in the (b2) is generated from a process gas that is the same as the process gas used in the (b1).
[G14] The etching method according to any one of G1 to G13, wherein the plasma generated in the (c) is generated from a process gas that is the same as the process gas used in the (b1).
[G15] The etching method according to any one of G1 to G14, wherein
the film is a silicon-containing film or a carbon-containing film, and
the process gas includes a fluorine-containing gas.
[G16] The etching method according to G15, wherein the fluorine-containing gas is a fluorocarbon gas.
[G17] The etching method according to any one of G1 to G16, wherein energy of ions supplied to the substrate in the (c) is higher than energy of the ions supplied to the deposit in the (b2).
[G18] A plasma processing apparatus including:
a chamber;
a substrate support provided in the chamber;
a radio frequency power supply configured to supply a source radio frequency power to generate a plasma in the chamber;
a bias power supply configured to supply an electric bias to the substrate support; and
a controller configured to control the radio frequency power supply and the bias power supply, wherein
the controller is configured to
(a) repeat a first cycle in which the controller controls the radio frequency power supply and the bias power supply to change at least one of a power level of the source radio frequency power or a level of the electric bias to two different levels in sequence in a state where a process gas having a deposit property is supplied into the chamber,
(b) control the radio frequency power supply and the bias power supply to generate a plasma of an etching gas after repetition of the first cycle, and
(c) repeat a second cycle including the (a) and (b).
[G19] An etching method including:
(a) preparing a substrate on a substrate support in a chamber of a plasma processing apparatus, the substrate including a film and a mask provided on the film;
(d) generating a plasma from a processing gas having a deposit property in the chamber;
(b) repeating a first cycle after the (d), the first cycle including
   (b1) forming a deposit on the substrate, the deposit being supplied to the substrate from a plasma generated from the process gas in the chamber, and
   (b2) supplying ions from a plasma to the deposit to modify the deposit; and
(c) etching the film by using a plasma generated in the chamber after the first cycle, wherein
a second cycle including the (d), the (b), and the (c) is repeated,
a power level S1 of a source radio frequency power used to generate the plasma from the process gas in the chamber in the (d), a power level S2 of the source radio frequency power in a period during which the (b1) is performed in the first cycle, a power level S3 of the source radio frequency power and a level B3 of an electric bias to attract ions to the substrate in a period during which the (b2) is performed in the first cycle, and a power level S4 of the source radio frequency power and a level B4 of the electric bias in a period during which the (c) is performed satisfy S1>S2>S3=S4 and B3<B4.
[G20] The etching method according to any one of G1 to G17 and G19, wherein a level of an electric bias supplied to the substrate support in the (c) increases stepwise or continuously.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) preparing a substrate on a substrate support in a chamber of a plasma processing apparatus, the substrate including a dielectric film containing silicon and oxygen and a metal hard mask provided on the dielectric film;
(b) forming a deposit on the substrate, the deposit being supplied from a plasma generated from a process gas containing a gas component containing fluorine and carbon in the chamber;
(c) supplying ions from a plasma generated from the process gas to the deposit to modify the deposit; and
(d) etching the dielectric film by using a plasma generated in the chamber after the (c), wherein
a power level of a source radio frequency power used to generate the plasma from the process gas in the (c) is equal to or lower than a power level of the source radio frequency power used to generate the plasma from the process gas in the (b),
a level of an electric bias supplied to the substrate support in the (c) is higher than a level of the electric bias supplied to the substrate support in the (b), or the electric bias is not supplied to the substrate support in the (b), and
a level of the electric bias supplied to the substrate support in the (d) is higher than the level of the electric bias supplied to the substrate support in the (c).

2. The etching method according to claim 1, wherein energy of the ions supplied to the deposit in the (c) is higher than energy of ions supplied to the substrate in the (b).

3. The etching method according to claim 1, wherein the process gas used in the (b) and the (c) is used to generate the plasma used in the (d).

4. The etching method according to claim 1, further comprising:
(e) generating a plasma from the process gas in the chamber after the (a) and before the (b),
wherein a power level of the source radio frequency power used to generate the plasma from the process gas in the (e) is higher than the power level of the source radio frequency power used to generate the plasma from the process gas in each of the (b) and the (c).

5. The etching method according to claim 1, wherein a cycle including (b), (c), and (d) is repeated.

6. The etching method according to claim 5, wherein
the cycle further includes (e) generating a plasma from the process gas in the chamber before the (b), and
a power level of the source radio frequency power used to generate the plasma from the process gas in the (e) is higher than the power level of the source radio frequency power used to generate the plasma from the process gas in each of the (b) and the (c).

7. The etching method according to claim 5, wherein
the cycle further includes (f) discharging a reaction product generated in the (d) from the chamber after the (d), and
the plasma is not generated in the chamber in the (f).

8. The etching method according to claim 1, wherein the metal hard mask contains at least one metal selected from the group consisting of titanium, tungsten, molybdenum, and ruthenium.

9. A plasma processing apparatus comprising:
a chamber;
a substrate support provided in the chamber;
a gas supply configured to supply a gas into the chamber;
a radio frequency power supply configured to supply a source radio frequency power to generate a plasma in the chamber;
a bias power supply configured to supply an electric bias to the substrate support; and
a controller configured to control the gas supply, the radio frequency power supply, and the bias power supply, wherein
the controller is configured to, in a state where a substrate including a dielectric film containing silicon and oxygen and a metal hard mask on the dielectric film is placed on the substrate support,
control the gas supply and the radio frequency power supply to generate a plasma from a process gas containing a gas component containing fluorine and carbon in the chamber to form a deposit on the substrate in a first operation,
control the gas supply, the radio frequency power supply, and the bias power supply to supply ions from a plasma generated from the process gas to the deposit to modify the deposit in a second operation, and
control the gas supply, the radio frequency power supply, and the bias power supply to etch the dielectric film by using a plasma generated in the chamber in a third operation after the deposit has been modified, and
the controller is configured to
set a power level of the source radio frequency power used to generate the plasma from the process gas in the second operation to a level equal to or lower than a power level of the source radio frequency power used to generate the plasma from the process gas in the first operation,
set a level of the electric bias supplied to the substrate support in the second operation to a level higher than a level of the electric bias supplied to the substrate support in the first operation, or not supply the electric bias to the substrate support in the first operation, and
set a level of the electric bias supplied to the substrate support in the third operation to a level higher than the level of the electric bias supplied to the substrate support in the second operation.

10. An etching method comprising:
(a) preparing a substrate on a substrate support in a chamber of a plasma processing apparatus, the substrate including a film and a mask provided on the film;
(b) repeating a first cycle including
(b1) forming a deposit on the substrate, the deposit being supplied to the substrate from a plasma generated from a process gas having a deposit property in the chamber, and
(b2) supplying ions from a plasma to the deposit to modify the deposit; and
(c) etching the film by using a plasma generated in the chamber, wherein
a second cycle including the (b) and the (c) is repeated,
a power level of a source radio frequency power used to generate the plasma in a period during which the (b1) is performed in the first cycle is higher than a power level of the source radio frequency power in a period during which the (b2) is performed in the first cycle,
a level of an electric bias supplied to the substrate support to attract the ions into the substrate in the period during which the (b2) is performed in the first cycle is higher than a level of the electric bias supplied to the substrate support in the period during which the (b1) is performed in the first cycle, or the electric bias is not supplied to the substrate support in the (b1), and
a level of the electric bias supplied to the substrate support in the (c) is higher than the level of the electric bias supplied to the substrate support in the (b2).

11. The etching method according to claim 10, wherein energy of the ions supplied to the deposit in the (b2) is higher than energy of ions supplied to the substrate in the (b1).

12. The etching method according to claim 10, wherein the second cycle further includes (d) generating a plasma from the process gas in the chamber before the (b).

13. The etching method according to claim 12, wherein a power level of the source radio frequency power supplied to generate the plasma from the process gas in the chamber in the (d) is higher than the power level of the source radio frequency power used in the first cycle.

14. The etching method according to claim 10, wherein the first cycle further includes (d) generating the plasma from the process gas in the chamber before the (b1).

15. The etching method according to claim 10, wherein
the second cycle further includes (e) discharging a reaction product generated in the (c) from the chamber after the (c), and
the plasma is not generated in the chamber in the (e).

16. The etching method according to claim 10, wherein
the second cycle further includes (g) stopping supply of the electric bias for attracting the ions into the substrate in a state where the source radio frequency power for generating the plasma in the chamber is supplied, and
the (g) is performed at least any one of before or after the (c).

17. The etching method according to claim 10, wherein the plasma generated in the (b2) is generated from a process gas that is the same as the process gas used in the (b1).

18. The etching method according to claim 10, wherein the plasma generated in the (c) is generated from a process gas that is the same as the process gas used in the (b1).

19. The etching method according to claim 10, wherein the level of the electric bias supplied to the substrate support in the (c) increases stepwise or continuously.
